(19) United States
(12) Patent Application Publication
(10) Pub. No.: US 2024/0393400 A1
(43) Pub. Date: Nov. 28, 2024

(54) METHOD AND SYSTEM FOR BATTERY ABNORMALITY DETECTION THROUGH ARTIFICIAL NEURAL NETWORK BATTERY MODEL BASED ON FIELD DATA

(71) Applicant: LG ENERGY SOLUTION, LTD., Seoul (KR)

(72) Inventors: Sung Yul YOON, Daejeon (KR); Ki Wook KWON, Daejeon (KR); Jeong Bin LEE, Daejeon (KR)

(73) Assignee: LG ENERGY SOLUTION, LTD., Seoul (KR)

(21) Appl. No.: 18/690,089

(22) PCT Filed: Jan. 27, 2023
(86) PCT No.: PCT/KR2023/001295

§ 371 Date: Mar. 7, 2024

(30) Foreign Application Priority Data
Mar. 30, 2022 (KR) 10-2022-0039370

(51) Int. Cl. G01R 31/367; G01R 19/00; G01R 19/165; G01R 31/371; G01R 31/3842; G01R 31/392; G01R 31/396

(52) U.S. Cl. CPC G01R 31/367; G01R 19/0038; G01R 19/16542; G01R 31/371; G01R 31/3842; G01R 31/392; G01R 31/396

(57) ABSTRACT

Discussed is a battery malfunctioning behavior detection system including a field data calculation unit configured to receive real-time measurement values from a battery in operation and calculate and output first field data from the real-time measurement values; a field data pre-processing unit configured to extract and output second field data for predicting a cell voltage from the first field data; an artificial intelligence neural network unit configured to receive an output of the field data pre-processing unit to predict the cell voltage and output a prediction value of the cell voltage; and a battery malfunctioning behavior detection unit configured to compare the prediction value output by the artificial intelligence neural network unit with the first field data and determine that it is malfunctioning behavior when a deviation between the prediction value and the first field data is greater than or equal to a predetermined range.

### CROSS REFERENCE TO RELATED APPLICATIONS

This application is the National Phase of PCT International Application No. PCT/KR2023/001295, filed on Jan. 27, 2023, which claims priority under 35 U.S.C. 119(a) to Patent Application No. 10-2022-0039370, filed in Republic of Korea on Mar. 30, 2022, all of which are hereby expressly incorporated by reference into the present application.

### TECHNICAL FIELD

The present invention relates to a battery malfunction detection method and system through a battery model. In particular, the present invention relates to a method and system for detecting battery malfunction through an artificial intelligence neural network battery model using field data rather than a conventional chemical/electrical equivalent circuit model in constructing the battery model.

### BACKGROUND ART

Conventionally, general Li-ion battery modeling was implemented using the chemical composition or electrical equivalent circuit. In the case of the corresponding battery modeling, modeling is basically performed based on cell test data including charging/discharging.

However, the internal cell test data is different from that of the actual field environment. In addition, even if an internal cell test is performed under various conditions, it may not be possible to secure sufficient data due to limitations in realistic experiments such as the number of cell samples, module/rack unit, degree of deterioration, temperature conditions, test equipment, and time.

In this regard, patent document 1 proposes a system for receiving measured initial characteristic data of a battery, training an artificial intelligence neural network, predicting long-term characteristic data therefrom, and determining the reliability thereof, and patent document 2 discloses a battery state estimation method in which physical quantity information of a battery is input to a battery training model and estimation information is obtained from the battery training model.

By the way, these conventional technologies are still insufficient to implement a method of estimating the state of the battery based on actual field data and determining whether or not the battery is malfunctioning.

Related prior art includes the following documents.
Patent Document 1: Korean Laid-open Patent Publication No. 10-2009-0020448
Patent Document 2: Korean Laid-open Patent Publication No. 10-2018-00572 66

### DISCLOSURE OF THE INVENTION

### Technical Problem

In order to solve the problems described above, the present invention is to provide a method and system for detecting malfunction of a battery cell by utilizing field data.

There is also a problem to be solved in utilizing the field data, which is that there are inevitably limitations on types of data collection items and the accuracy thereof is low.

In order to solve this problem, it is intended to provide a battery malfunction detection method and system in which a battery modeling through AI training is implemented in order to model a battery by utilizing various field data and which uses the battery modeling.

### Technical Solution

In order to solve the problems described above, according to the present invention, there is provided, as a system for detecting malfunctioning behavior of a battery, a battery malfunctioning behavior detection system configured to include a field data calculation unit that is configured to receive real-time measurement values from a battery in operation and calculate and output first field data from the real-time measurement values, a field data pre-processing unit that is configured to extract and output second field data for predicting a cell voltage from the first field data, an artificial intelligence neural network unit that is configured to receive an output of the field data pre-processing unit to predict the cell voltage and output a prediction value of the cell voltage, and a battery malfunctioning behavior detection unit that is configured to compare the prediction value output by the artificial intelligence neural network unit with the first field data and determine that it is a malfunctioning behavior when a deviation between the prediction value and the first field data is greater than or equal to a predetermined range.

The artificial intelligence neural network unit may be configured to include a cell voltage prediction model that is trained using the second field data corresponding values for predicting the cell voltage calculated from a standard battery rather than a battery for which the first field data is calculated, as training data, receives the second field data for predicting the cell voltage, and outputs the prediction value of the cell voltage of the next cycle, a cell temperature prediction model that is trained using the third field data corresponding values for predicting the cell temperature calculated from the standard battery rather than the battery for which the first field data is calculated, as training data, receives the third field data for predicting the cell temperature, and outputs the prediction value of the cell temperature of the next cycle, and may further include a neural network training unit that re-trains and updates the cell voltage prediction model and the cell temperature prediction model by adding the first field data for a predetermined period of a normal operation section of the battery as new training data.

According to the present invention, there is also provided a battery malfunctioning behavior detection method configured to include a field data calculation process of measuring and calculating real-time battery state information data from a battery in operation, a field data pre-processing process including a field data pre-processing process for cell voltage prediction of extracting data for cell voltage prediction from calculated field data, a real-time prediction process including a cell voltage prediction process of inputting data for predicting cell voltage into a cell voltage prediction model and calculating a cell voltage prediction value of the next cycle, and a battery malfunctioning behavior detection process including a cell voltage malfunctioning behavior detection process of comparing the cell voltage prediction value with a cell voltage value of the field data and generating a cell voltage malfunctioning behavior detection signal when a deviation is greater than or equal to a predetermined range.

In this case, the data for predicting the cell voltage may be time-series values of rack current, ambient temperature, fan on-off information, module state of charge (SOC), cell state of health (SOH), and cell voltage for each battery cell and battery module constituting the battery, and the data for predicting the cell temperature may be time series values of cell temperature, ambient temperature, and fan on/off information for each battery cell and battery module constituting the battery.

### Advantageous Effects

According to the present invention, it is possible to predict battery temperature value and voltage value in real time using battery field data and compare the predicted battery temperature value and voltage value with actual temperature value and voltage value to detect in real-time whether or not the battery operates abnormally.

### BRIEF DESCRIPTION OF THE DRAWINGS

The following drawings attached to this specification are intended to illustrate a preferred embodiment of the present invention, and serve to make further understand the technical idea of the present invention together with the detailed description of the invention described above, and thus the present invention should not be construed as being limited only to the matters described in the drawings.

FIG. 1 is a diagram illustrating an example of respective pieces of field data measured and calculated in the present invention.

FIG. 2 is a diagram illustrating an example of extracting training data by pre-processing field data acquired during a certain section or for a predetermined time, from among the field data of FIG. 1.

FIG. 3 is a diagram illustrating a sequence of a battery malfunctioning behavior detection method according to the present invention.

FIG. 4 illustrates a graph illustrating field data values of cell temperature and prediction values of cell temperature over time.

FIG. 5 is a block diagram of a battery malfunctioning behavior detection system according to the present invention.

### MODE FOR CARRYING OUT THE INVENTION

The present invention trains a prediction model using field data to predict voltage and temperature at a next time point. Types of field data used in the present invention are as follows.

### 1. Field Data

In the present invention, ‘field data’ means the following data measured in real time from a battery in operation and the following data calculated therefrom. The field data are time-series data of battery state information calculated during battery operation at predetermined time intervals.

The types of field data used in the present invention are as follows.

### (1) Rack Data

The rack data is data of a battery rack. The rack data includes rack current, ambient temperature, and fan on/off information. These are usually measured and calculated by a rack battery management system (BMS).

The rack current can be expressed as Rack.Current, ambient temperature as Ambient.Temp, and fan on/off information as Fan_ON/OFF flag value, and they are measured at predetermined time intervals.

The values of the rack current, ambient (Ambient Temp.), and Fan.ON values of Fan ON/OFF information at time t measured at a predetermined cycle can be expressed as Rack.Current(t), Ambient.Temp(t), Fan.ON(t). In this case, the values of Rack.Current(t) and Ambient.Temp(t) have measured values of appropriate measurement sensors, and Fan.ON(t) can have a value of ‘1’ when the fan is running and ‘0’ when the fan is not running.

For example, when measured at 1-second intervals, the rack current, ambient temperature, and fan on/off information (if the fan is running) at 3 seconds after driving can be respectively expressed as Rack.Current(3), Ambient.Temp(3), and Fan.ON(3).

### (2) Module Data

The module data is data of each of a plurality of battery modules included in the battery rack. The module data includes an SOC value of each module, and when there are i modules constituting the battery rack, each module is expressed as Mk (k=1, 2, 3, . . . i), and the SOC value of each module (SOC M) is expressed as SOC.Mk. For example, the SOC value of the second module is expressed as SOC.M2. The module data is usually measured and calculated by a module battery management system (BMS).

Like the rack data, the SOC.Mk value can be measured at predetermined time intervals, and the SOC.Mk value at time t is denoted as SOC.Mk(t).

### (3) Cell Data

The cell data is data of each of a plurality of battery cells included in the battery module. The cell data includes a cell voltage value Cell V as a voltage measurement value of each cell, and the cell voltage value is denoted as Cell.V.MkCj (k=1, 2, 3, . . . m). For example, the cell voltage value of the third cell of the second module and is denoted as Cell_V_M2C3. The cell data is usually measured and calculated by a cell battery management system (BMS) or, a module battery management system (BMS) when there is no cell BMS.

The Cell.V.MkCj value can also be measured at predetermined time intervals, and the Cell.V.MkCj value at time t is denoted as Cell.V.MkCj(t).

The cell data may include cell temperature. The cell temperature of j-th cell of the k-th module at time t is denoted as Cell.T.MkCj(t).

### (4) Calculated Value

The present invention also uses an SOH value SOH MkCj as one of the calculated values. The SOH value of each cell is calculated by the cell battery management system (BMS), the module battery management system (BMS) or the rack battery management system (BMS), and the SOH of a specific cell is denoted as SOH.MkCj (k=1, 2, 3, . . . m).

The SOH.MkCj value can also be measured at predetermined time intervals, and the SOH.MkCj value at time t is denoted as SOH.MkCj(t).

### 2. Battery Malfunctioning Behavior Detection Method

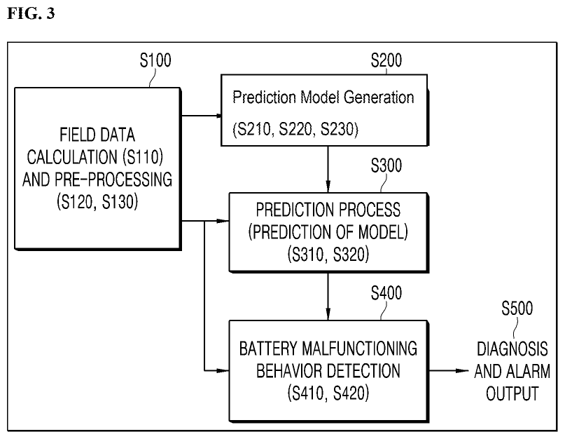

The battery malfunctioning behavior detection method according to the present invention will be described with reference to FIG. 3.

### 2-1. Calculation and Pre-Processing Process of Field Data (S100)

This process is a procedure for measuring, calculating, and pre-processing the field data described above.

### (1) Field Data Calculation Process (S110)

The field data calculation process is a process of measuring and calculating battery state information data in real-time from a battery in operation.

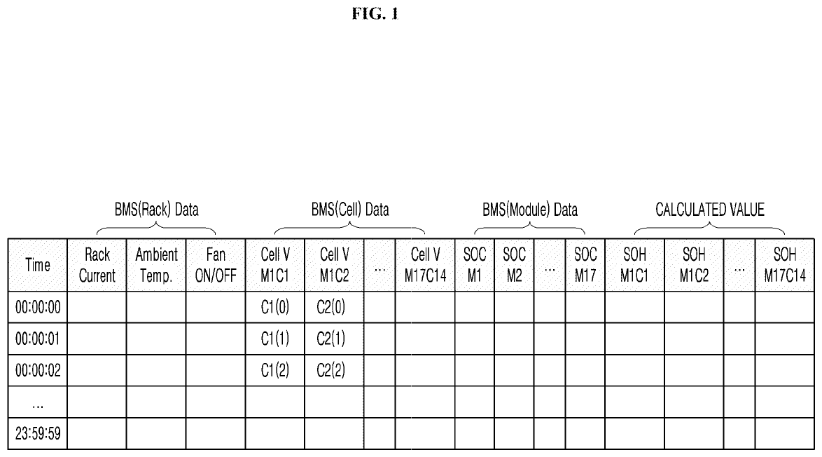

Measurement and calculation of field data is performed in real time from the battery in operation in a predetermined time unit, and FIG. 1 illustrates an example of each field data measured and calculated in the present invention.

The measurement and calculation of field data can be performed in each cell battery management system (BMS), module battery management system (BMS) or rack battery management system (BMS), and the field data is transmitted to the field data calculation unit 100. The field data calculation unit may be configured to be integrated into the rack BMS.

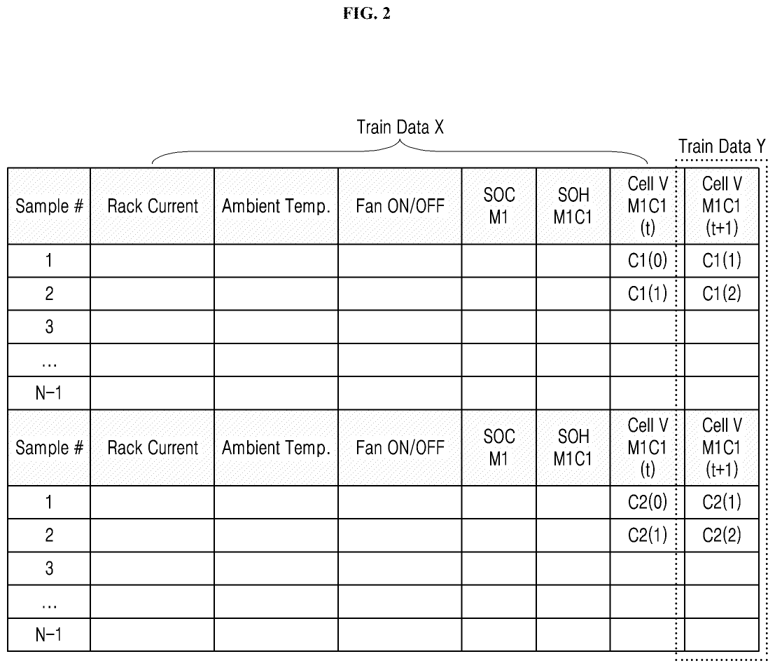

Among the field data shown in FIG. 1 and described above, field data obtained in a certain section or for a predetermined time are pre-processed and extracted as training data as shown in FIG. 2.

### (2) Field Data Pre-Processing Process for Cell Voltage Prediction (S120)

The field data pre-processing process for cell voltage prediction is a field data pre-processing process for cell voltage prediction of extracting data for cell voltage prediction from the calculated field data.

In the present invention, a cell voltage is predicted using a cell voltage prediction model that predicts the cell voltage from field data. As data for cell voltage prediction, as shown in FIG. 2, the rack current, ambient temperature, SOC, SOH, and cell voltage of the previous cycle are used as input values.

To this end, in the pre-processing process, Rack.Current(t), Ambient.Temp(t), Fan.ON(t), SOC.Mk(t), SOH.MkCj(t), and Cell.V.MkCj(t) values, which are rack current, ambient temperature, SOC, SOH, cell voltage values, are periodically extracted from the field data calculated in real time at a predetermined cycle. FIG. 2 illustrates a data format for extracting Rack.Current(t), Ambient.Temp(t), Fan.ON(t), SOC.Mk(t) values for each time cycle and SOH_M1C2(t) and Cell_V_M1C2(t) values of cells 1 and 2 of module 1 corresponding to them.

### (3) Field Data Pre-Processing Process for Cell Temperature Prediction (S130)

The field data pre-processing for cell temperature prediction is a process of extracting data for predicting the cell temperature calculated from the calculated field data.

In the present invention, a cell temperature is predicted using a cell cell temperature prediction model that predicts the cell temperature from field data. As data for cell temperature prediction, the cell temperature of the next cycle is predicted using Cell.T.MkCj(t), which is the current temperature value of the cell, ambient temperature Ambient.Temp(t), and Fan.ON(t).

To this end, in the pre-processing process, the Cell.T.MkCj(t), Ambient.Temp(t), and Fan.ON(t) values are periodically extracted from field data calculated in real time at a predetermined cycle.

### 2-2. Prediction Model Generation Process (S200)

### (1) Cell Voltage Prediction Model Generation Process (S210)

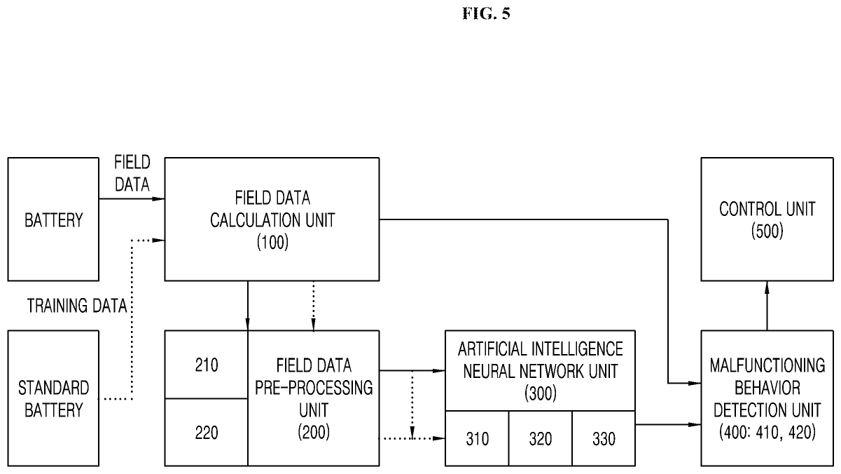

A cell voltage prediction model 210 for cell voltage prediction is generated by conducting supervised learning by inputting Rack.Current(t), Ambient.Temp(t), Fan.ON(t), SOC.Mk(t), SOH.MkCj(t), Cell.V.MkCj(t) to a predetermined artificial intelligence neural network and using the output value thereof as Cell.V.MkCj(t+1). The cell voltage prediction model is generated using a predetermined artificial intelligence neural network. A known artificial intelligence neural network can be used as the artificial intelligence neural network, and the artificial intelligence neural network that has been trained with predetermined training data is stored as the cell voltage prediction model 210 of FIG. 5.

As the training data of the cell voltage prediction model 210, the Rack.Current(t), Ambient.Temp(t), Fan.ON(t), SOC.Mk(t), SOH.MkCj(t), Cell.V.MkCj(t) values for a predetermined time section pre-processed through the field data pre-processing process (S120) for cell voltage prediction are used as input values to the neural network and Cell.V.MkCj(t+1), which is the cell voltage measurement value of the next cycle, is used as the output value thereof, and the cell voltage prediction model is generated by conducting supervised learning on the artificial intelligence neural network so that when the Rack.Current(t), Ambient.Temp(t), Fan.ON(t), SOC.Mk(t), SOH.MkCj(t), Cell.V.MkCj(t) values for a predetermined time section are input to the artificial intelligence neural network, the output value becomes Cell.V.MkCj(t+1), which is the cell voltage measurement value of the next cycle.

The artificial intelligence neural network trained in this way is stored as the cell voltage prediction model 210, which receives the Rack.Current(t), Ambient.Temp(t), Fan.ON(t), SOC.Mk(t), SOH.MkCj(t), Cell.V.MkCj(t) values, and calculates Cell.Vprdic.MkCj(t+1), which is the cell voltage prediction value of the next cycle.

The Rack.Current(t), Ambient.Temp(t), Fan.ON(t), SOC.Mk(t), SOH.MkCj(t), Cell.V.MkCj(t), Cell.V.MkCj(t+1) values, which are the training data used in the cell voltage prediction model generation process, may be field data measured at a different time from data used in a cell voltage prediction process (S310) below, and may be sample data obtained before battery operation or through operation of sample batteries.

In another embodiment, the cell voltage prediction model may be generated by using Rack.Current(t), Ambient.Temp(t), Fan.ON(t), SOC.Mk(t), SOH.MkCj(t), Cell.V.MkCj(t), Cell.V.MkCj(t+1) for a predetermined time section as training data of the cell voltage prediction model 210, not field data.

That is, the cell voltage prediction model is generated by being trained using data corresponding values for predicting cell voltage calculated from a standard battery rather than a battery in operation for which the field data is calculated, as training data. Thereafter, the cell voltage prediction model receives data for predicting the cell voltage from the battery in operation and outputs a prediction value of the cell voltage of the next cycle.

### (2) Cell Temperature Prediction Model Generation Process (S220)

In the present invention, a cell temperature prediction model is also included. The cell temperature prediction model 220 for cell temperature prediction is also generated in the same manner as the cell voltage prediction model generation process, using the pre-processed data as training data. That is, supervised learning is conducted by periodically inputting Cell.T.MkCj(t), Ambient.Temp(t), Fan.ON(t) values to a predetermined artificial intelligence neural network, and using the output value thereof as Cell.T.MkCj(t+1). The cell voltage prediction model is generated by conducting supervised learning on the artificial intelligence neural network so that Cell.T.MkCj(t), Ambient.Temp(t), Fan.ON(t) values are periodically input for a predetermined time as input data of artificial intelligence neural network and the output value becomes Cell.T.MkCj(t+1), which is the cell temperature measurement value of the next cycle.

The artificial intelligence neural network trained in this way is stored as the cell temperature prediction model 220, which receives the Cell.T.MkCj(t), Ambient.Temp(t), Fan.ON(t) values and calculates Cell.T_{predic}.MkCj(t+1), which is the cell temperature prediction value of the next cycle.

The Cell.T.MkCj(t), Ambient.Temp(t), Fan.ON(t), Cell.T.MkCj(t+1) values, which are the training data used in the cell temperature prediction model generation process, may be field data measured at a different time from data used in the cell temperature prediction process (S320) below, and may be sample data obtained before battery operation or through operation of sample batteries.

In another embodiment, the cell temperature prediction model may be generated by using the Cell.T.MkCj(t), Ambient.Temp(t), Fan.ON(t), Cell.T.MkCj(t+1) values for a predetermined time section calculated using a standard battery in a laboratory as training data, not field data.

That is, the cell temperature prediction model 220 is generated by being trained using data corresponding values for predicting cell temperature calculated from the standard battery rather than a battery in operation for which the field data is calculated as training data, and receives data for predicting the cell temperature from the battery in operation and outputs a prediction value of the cell temperature of the next cycle.

### (3) Prediction Model Update Process (S230)

Another embodiment is a process of re-training and updating the cell voltage prediction model and the cell temperature prediction model by adding field data for a predetermined period of a normal operation section of the battery in operation, for which the field data is calculated, as new training data.

In the cell voltage prediction model generation process, the cell voltage prediction model 210 may be updated by inputting the Rack.Current(t), Ambient.Temp(t), Fan.ON(t), SOC.Mk(t), SOH.MkCj(t), Cell.V.MkCj(t), Cell.V.MkCj(t+1) values for a predetermined time calculated while the battery does not exhibit malfunctioning behavior as new training data. In this case, since the training model is updated by applying actual field data, it is possible to obtain a more accurate prediction value for the actual battery disposed in the field.

In the cell temperature prediction model generation process, the cell temperature prediction model 220 may be updated by inputting Cell.T.MkCj(t), Ambient.Temp(t), Fan.ON(t), Cell.T.MkCj(t+1) values for a predetermined time calculated while the battery does not exhibit malfunctioning behavior as new learning data. In this case, since the training model is updated by applying actual field data (S230), it is possible to obtain a more accurate prediction value for the actual battery disposed in the field.

### 2-3. Real-Time Prediction Process (S300)

The real-time prediction process is a procedure for predicting cell voltage and cell temperature using the cell voltage prediction model and cell temperature prediction model for which the training has been completed.

### (1) Cell Voltage Prediction Process (S310)

The cell voltage prediction process is a procedure for inputting Rack.Current(t), Ambient.Temp(t), Fan.ON(t), SOC.Mk(t), SOH.MkCj(t), Cell.V.MkCj(t) values pre-processed and extracted in the field data pre-processing process (S120) for cell voltage prediction to the generated or updated cell voltage prediction model 210 and calculating Cell.V_{prdic}.MkCj(t+1), which is a cell voltage prediction value of the next cycle.

### (2) Cell Temperature Prediction Process (S320)

In the cell temperature prediction process, the Cell.T.MkCj(t), Ambient.Temp(t), Fan.ON(t) values extracted in the pre-processing process (S220) are input into the generated or updated cell temperature prediction model 220 and calculating Cell.T_{predic}.MkCj(t+1), which is the cell temperature prediction value of the next cycle.

### 2-4. Battery Malfunctioning Behavior Detection Process (S400)

### (1) Cell Voltage Malfunctioning Behavior Detection Process (S410)

This cell voltage malfunctioning behavior detection process is a process of detecting a case in which the Cell.V_{prdic}.MkCj(t+1) value, which is a prediction value output by the cell voltage prediction model 210 through the cell voltage prediction process (S310), is compared with and the Cell.V.MkCj(t+1) value of the field data calculated from the battery and a difference greater than or equal to a predetermined reference value occurs. When the difference greater than or equal to the predetermined reference value occurs, a cell voltage malfunctioning behavior detection signal) is generated.

### (2) Cell Temperature Malfunctioning Behavior Detection Process (S420)

This cell temperature malfunctioning behavior detection process is a process of detecting a case in which the Cell.T_{predic}.MkCj(t+1) value, which is a prediction value output by the cell temperature prediction model 220 through the cell temperature prediction process (S320), is compared with the Cell.T.MkCj(t+1) value in field data calculated from the battery and a difference greater than or equal to a predetermined reference value occurs. When the difference greater than or equal to a predetermined reference value occurs, a cell temperature malfunctioning behavior detection signal is generated.

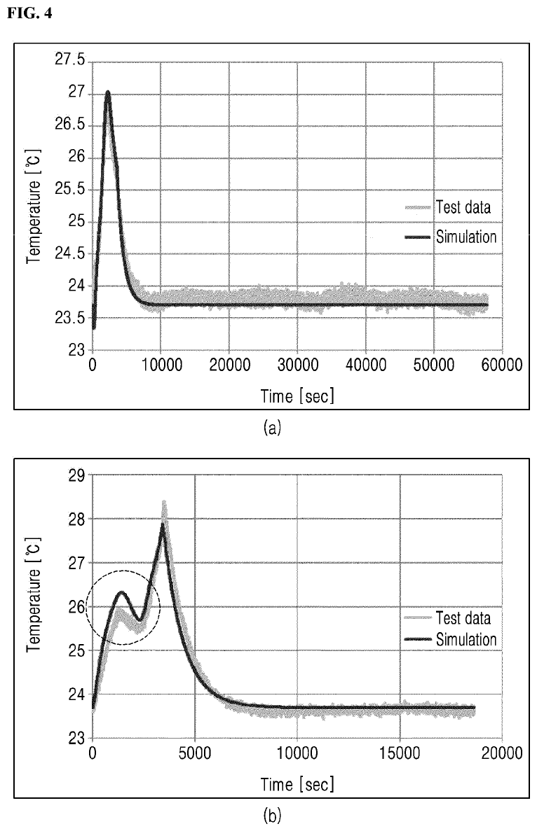

When describing an example of the detection with reference to FIG. 4, the Cell.T.MkCj(t+1) values which are field data are indicated as ‘test data’ and the Cell.Tpredic.MkCj(t+1) which are prediction value are indicated as ‘simulation’. As illustrated in (a) of FIG. 4, when the deviation greater than or equal to a predetermined reference value does not occur between the field data and the prediction value, it is determined as normal behavior, and, as illustrated in (b) of FIG. 4, when the deviation greater than or equal to the predetermined reference value occurs between the field data and the prediction value, it is determined and detected as battery malfunctioning behavior.

### 2-5. Diagnosis and Alarm Generation Process (S500)

The diagnosis and alarm generation process is a procedure for performing a diagnosis procedure or generating an alarm externally when the difference between the Cell.Vprdic.MkCj(t+1) value, Cell.Tpredic.MkCj(t+1) values and the Cell.V.MkCj(t+1) value, Cell.T.MkCj(t+1) value, which is greater than or equal to a reference value, occurs.

In the present invention, the diagnostic procedure is not limited to a specially defined procedure, and when the deviation greater than or equal to the reference value occurs more than a predetermined number of times during a predetermined time section, an alarm generation signal may be output or a control signal for blocking a battery charging or discharging operation may be output.

### 3. Battery Malfunctioning Behavior Detection System

Referring to FIG. 5, a battery malfunctioning behavior detection system according to the present invention will be described.

### 3-1. Field Data Calculation Unit 100

The field data calculation unit 100 receives real-time measurement values from the battery in operation, calculates field data values from the received data, and outputs the calculated values. Measurement and calculation of field data may be performed in each cell battery management system (BMS), module battery management system (BMS), or rack battery management system (BMS), and the field data are transmitted to the field data calculation unit 100. The field data calculation unit may be configured to be integrated into the rack BMS. The measurement values received from the battery are values received from respective sensors installed in the battery, and include normal battery state information measurement values. The calculated field data are field data of the present invention described above.

The field data calculation unit transmits the field data to the field data pre-processing unit 200.

### 3-2. Field Data Pre-Processing Unit 200

The field data pre-processing unit 200 is configured to include a cell voltage prediction field data pre-processing unit 210 that extracts field data for cell voltage prediction and a cell temperature prediction field data pre-processing unit 220 that extracts field data for cell temperature prediction, from the field data calculated by the field data calculation unit 210, and performs the field data pre-processing process for cell voltage prediction (S120) and the field data pre-processing process for cell temperature prediction (S130).

The field data pre-processing unit 200 transmits training data and field data to the artificial intelligence neural network unit 300.

In this case, the training data, as indicated by the path of the arrow shown by the dotted line in FIG. 5, may be provided to the artificial intelligence neural network unit 300 by calculating data corresponding to each item constituting field data from a standard battery, of which normal quality has been verified in a laboratory, for a predetermined period of time. That is, the cell voltage prediction model 320 constituting the artificial intelligence neural network unit is trained using field data corresponding values for predicting cell voltage calculated from the standard battery as training data, and the cell temperature prediction model 330 may be trained using field data corresponding values for predicting cell temperature calculated from the standard battery as training data.

In another embodiment, a configuration in which the training data is provided to the artificial intelligence neural network unit 300 by extracting field data for a certain period of time as training data during battery operation may be adopted.

Meanwhile, regardless of which of the two types of data is used as training data, the field data pre-processing unit 200 may provide the field data of the battery in the normal operation section as the training data so that the pre-trained artificial intelligence neural networks 320 and 330 are trained.

### 3-3. Artificial Intelligence Neural Network Unit 300

### (1) Neural Network Training Unit 310

The neural network training unit 310 receives the training data described above from the field data pre-processing unit 200 and trains the artificial intelligence neural network. The artificial intelligence neural network is trained as the cell voltage prediction model 320 and the cell temperature prediction model 330, and in the the neural network training unit, the prediction models are trained to predict cell voltage and cell temperature, respectively, and stored.

The neural network training unit 310 can also be controlled to retrain the artificial intelligence neural network by adding field data for a predetermined period of the battery normal operation section as new training data at a predetermined cycle or under the control of the control unit 500 so as to update the prediction models 320 and 330.

For example, while the prediction models 320 and 330 are trained and operated with the training data provided from the standard battery and generate prediction values by receiving field data, by re-training the prediction models 320 and 330 by adding field data in a section during which malfunctioning behavior is not detected by the battery malfunctioning behavior detection unit 400 described later, that is, in a normal section, to the training data, the prediction models 320 and 330 are trained to reflect field data generated from the operating state of the actual field battery, which improves the prediction accuracy of the prediction models 320 and 330.

The artificial intelligence neural networks which have been trained with the training data or which have been re-trained is updated by adding field data is stored as the cell voltage prediction model 320 and the cell temperature prediction model 330, respectively.

### (2) Cell Voltage Prediction Model 320

The cell voltage prediction model 320 is a trained artificial intelligence neural network that receives field data for cell voltage prediction from the field data pre-processing unit 200 and predicts cell voltage of the next cycle. The field data for cell voltage prediction may be Rack.Current(t), Ambient.Temp(t), Fan.ON(t), SOC.Mk(t), SOH.MkCj(t), Cell.V.MkCj(t) values, and Cell.V_{prdic}.MkCj(t+1), which is a cell voltage prediction value, is calculated by receiving these values.

### (3) Cell Temperature Prediction Model 330

The cell temperature prediction model 330 is a trained artificial intelligence neural network that receives field data for cell temperature prediction from the field data pre-processing unit 200 and predicts the cell temperature of the next cycle. The field data for cell temperature prediction may be Cell.T.MkCj(t), Ambient.Temp(t), Fan.ON(t) values, and Cell.Tpredic.MkCj(t+1), which is a cell temperature prediction value, is calculated by receiving these values.

### 3-4. Battery Malfunctioning Behavior Detection Unit 400

The battery malfunctioning behavior detection unit 400 compares prediction values of cell voltage and cell temperature calculated by the cell voltage prediction model 320 and the cell temperature prediction model 330 of the artificial intelligence neural network unit 300 with cell voltage and cell temperature of field data, detects malfunctioning behavior of the battery, and transmits a malfunctioning behavior detection signal to a control unit. The malfunctioning behavior detection signal may include at least one or both of a cell voltage malfunctioning behavior signal and a cell temperature malfunctioning behavior signal, which will be described later.

The battery malfunctioning behavior detection unit 400 receives field data output by the field data calculation unit and the prediction value output by the artificial intelligence neural network unit 300.

### (1) Cell Voltage Malfunctioning Behavior Determination Unit 410

The cell voltage malfunctioning behavior determination unit 410 compares the Cell.V_{prdic}.MkCj(t+1) value described above with the Cell.V.MkCj(t+1) value of the field data, and determines that it is the cell voltage malfunctioning behavior when the deviation is greater than or equal to a predetermined range, and transmits the cell voltage malfunctioning behavior signal to the control unit.

### (2) Cell Temperature Malfunctioning Behavior Determination Unit 420

The cell temperature malfunctioning behavior determination unit 420 compares the Cell.T_{predic}.MkCj(t+1) value described above with the Cell.T.MkCj(t+1) value of the field data, determines that it is the cell temperature malfunctioning behavior when the deviation is greater than or equal to the predetermined range, and transmits the cell temperature malfunctioning behavior signal to the control unit.

### 3-5. Control Unit 500

The control unit 500 receives the malfunctioning behavior detection signal from the malfunctioning behavior detection unit 400 and performs the diagnosis and alarm generation process (S500) described above.

The control unit may be respectively connected to the field data calculation unit, the field data pre-processing unit, the prediction model, and the malfunctioning behavior detection unit to control respective configurations. In another embodiment, all configurations of the field data calculation unit, the field data pre-processing unit, the prediction model, and the malfunctioning behavior detection unit may be physically integrated to be configured as the control unit. In this case, the integrated control unit may be implemented by being directly connected to the rack BMS of the battery or integrated into the rack BMS.

1. A battery malfunctioning behavior detection system comprising:
a field data calculation unit configured to receive real-time measurement values from a battery in operation and calculate and output first field data from the real-time measurement values;
a field data pre-processing unit configured to extract and output second field data for predicting a cell voltage from the first field data;
an artificial intelligence neural network unit configured to receive an output of the field data pre-processing unit to predict the cell voltage and output a prediction value of the cell voltage; and
a battery malfunctioning behavior detection unit configured to compare the prediction value output by the artificial intelligence neural network unit with the first field data and determine that it is a malfunctioning behavior when a deviation between the prediction value and the first field data is greater than or equal to a predetermined range.

2. The battery malfunctioning behavior detection system of claim 1, wherein the field data pre-processing unit is configured to additionally extract and output third field data for predicting cell temperature,
wherein the artificial intelligence neural network unit is configured to receive the output of the field data pre-processing unit, additionally predict the cell temperature, and output a prediction value of the cell temperature, and
wherein the battery malfunctioning behavior detection unit is configured to determine that it is battery malfunctioning behavior when the cell voltage prediction value output by the artificial intelligence neural network unit is compared with a cell voltage value of the first field data and a deviation between a predicted cell voltage value and the cell voltage value is greater than or equal to a predetermined range, or when a cell temperature prediction value output by the artificial intelligence neural network unit is compared with a cell temperature value of the first field data and a deviation between the cell temperature prediction value and the cell temperature value is greater than or equal to a predetermined range.

3. The battery malfunctioning behavior detection system of claim 2, wherein the second field data for predicting the cell voltage are time-series values of rack current, ambient temperature, fan on-off information, module state of charge (SOC), cell state of health (SOH), and cell voltage for each battery cell and battery module constituting the battery, and
wherein the third field data for predicting the cell temperature are time series values of cell temperature, ambient temperature, and fan on/off information for each battery cell and battery module constituting the battery.

4. The battery malfunctioning behavior detection system of claim 3, wherein the artificial intelligence neural network unit is configured to receive the second field data for predicting the cell voltage and output the prediction value of the cell voltage of the next cycle, and receive the third field data for predicting the cell temperature and output the prediction value of the cell temperature of the next cycle.

5. The battery malfunctioning behavior detection system of claim 4, wherein the artificial intelligence neural network unit comprises:
a cell voltage prediction model that is trained using the second field data corresponding values for predicting the cell voltage calculated from a standard battery rather than a battery for which the first field data is calculated, as training data, receives the second field data for predicting the cell voltage, and outputs the prediction value of the cell voltage of the next cycle, and
a cell temperature prediction model that is trained using the third field data corresponding values for predicting the cell temperature calculated from the standard battery rather than the battery for which the first field data is calculated, as training data, receives the third field data for predicting the cell temperature and outputs the prediction value of the cell temperature of the next cycle.

6. The battery malfunctioning behavior detection system of claim 5, wherein the artificial intelligence neural network unit further comprises a neural network training unit that re-trains and updates the cell voltage prediction model and the cell temperature prediction model by adding the first field data for a predetermined period of a normal operation section of the battery as new training data.

7. A battery malfunctioning behavior detection method comprising:
a field data calculation process of measuring and calculating real-time battery state information data from a battery in operation;
a field data pre-processing process including a field data pre-processing process for cell voltage prediction of extracting data for cell voltage prediction from calculated field data;
a real-time prediction process including a cell voltage prediction process of inputting data for predicting cell voltage into a cell voltage prediction model and calculating a cell voltage prediction value of the next cycle; and
a battery malfunctioning behavior detection process including a cell voltage malfunctioning behavior detection process of comparing the cell voltage prediction value with a cell voltage value of the field data and generating a cell voltage malfunctioning behavior detection signal when a deviation is greater than or equal to a predetermined range.

8. The battery malfunctioning behavior detection method of claim 7, wherein the field data pre-processing process further comprises a field data pre-processing process for cell temperature prediction of extracting data for predicting cell temperature from the calculated field data,
wherein the real-time prediction process further comprises a cell temperature prediction process of inputting data for predicting cell temperature into a cell temperature prediction model and calculating a cell temperature prediction value of the next cycle, and
wherein the battery malfunctioning behavior detection process further comprises a cell temperature malfunctioning behavior detection process of comparing the cell temperature prediction value with a cell temperature value of the field data and generating a cell temperature malfunctioning behavior detection signal when a deviation between the cell temperature prediction value and the cell temperature value is greater than or equal to a predetermined range.

9. The battery malfunctioning behavior detection method of claim 8, wherein the data for predicting the cell voltage are time-series values of rack current, ambient temperature, fan on-off information, module state of charge (SOC), cell state of health (SOH), and cell voltage for each battery cell and battery module constituting the battery, and
wherein the data for predicting the cell temperature are time series values of cell temperature, ambient temperature, and fan on/off information for each battery cell and battery module constituting the battery.

10. The battery malfunctioning behavior detection method of claim 9, wherein the cell voltage prediction model is trained using data corresponding values for predicting the cell voltage calculated from a standard battery rather than a battery in operation for which the field data is calculated, as training data, receives the data for predicting the cell voltage from the battery in operation, and outputs the prediction value of the cell voltage of the next cycle, and
wherein the cell temperature prediction model is trained using data corresponding values for predicting the cell temperature calculated from a standard battery rather than the battery in operation for which the field data is calculated, as training data, and receives the data for predicting the cell temperature, and outputs the prediction value of the cell temperature of the next cycle.

11. The battery malfunctioning behavior detection method of claim 10, further comprising:
a prediction model update process of re-training and updating the cell voltage prediction model and the cell temperature prediction model by adding field data for a predetermined period of a normal operation section of the battery in operation that calculates the field data as new training data,
wherein, in the real-time prediction process, the data for predicting cell voltage and the data for predicting cell temperature are input to the cell voltage prediction model and the cell temperature prediction model updated through the prediction model update process to calculate the cell voltage prediction value and cell temperature prediction value of the next cycle.

12. The battery malfunctioning behavior detection method of claim 7, further comprising an alarm generation process of outputting an alarm generation signal or outputting a control signal for blocking a battery charging or discharging operation, when a malfunctioning behavior is detected.

13. The battery malfunctioning behavior detection system of claim 1, further comprising a control unit configured to output an alarm generation signal or output a control signal for blocking a battery charging or discharging operation, when a malfunctioning behavior is detected.
